(19) United States
(12) Patent Application Publication
(10) Pub. No.: US 2006/0085726 A1
(43) Pub. Date: Apr. 20, 2006

(54) Apparatus and method for decoding Reed-Solomon code

(75) Inventors: Jong-Hun Rhee, Suwon-si (KR); Min-goo Kim, Yongin-si (KR); Su-Yean Kim, Incheon (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/239,689

(22) Filed: Sep. 30, 2005

(30) Foreign Application Priority Data
Oct. 1, 2004 (KR) 2004-78472

(51) Int. Cl. H03M 13/00

(52) U.S. Cl. 714/784

(57) ABSTRACT

An apparatus for receiving and decoding a double-coded symbol in a communication system using a double coding scheme for encoding a Reed-Solomon (RS)-coded symbol with a predetermined scheme for communication. In the apparatus, an inner decoder receives a frame formed with the double-coded symbols, and primary-decodes the received frame. An RS decoding buffer stores an output of the inner decoder frame by frame, and an RS decoder reads symbols in the same column from symbols of a frame stored in the RS decoding buffer, performs RS decoding on the read symbols, and generates an RS decodable indicator value for each symbol. A log likelihood ratio (LLR) update unit updates an LLR value using the RS decodable indicator value, and outputs the updated LLR value to the inner decoder.

### PRIORITY

This application claims the benefit under 35 U.S.C. § 119(a) of an application entitled “Apparatus and Method for Decoding Reed-Solomon Code” filed in the Korean Intellectual Property Office on Oct. 1, 2004 and assigned Serial No. 2004-78472, the entire contents of which are hereby incorporated by reference.

### BACKGROUND OF THE INVENTION

1. Field of the Invention

The present invention relates generally to an apparatus and method for decoding coded symbols. More particularly, the present invention relates to an apparatus and method for decoding symbols encoded by Reed-Solomon coding.

2. Description of the Related Art

Generally, various coding methods are used to acquire data stability in the process of storing or transmitting data. A mobile communication system uses a convolutional coding method, a turbo coding method, or a Reed-Solomon (RS) coding method as a typical coding method in order to transmit data safely. The mobile communication system may use only one of the coding methods, or two or more of the coding methods together. When a transmitter reads symbols recorded in a storage medium after being encoded by the coding methods and transmits the read symbols, a receiver must decode the coded data into the original data, that is, the original information. Therefore, a communication system or a data acquisition apparatus requires a decoding apparatus.

For convenience, it will be assumed herein that when a communication system transmits data, a decoding apparatus acquires the original data, or original information, from the received coded symbols.

When an error occurs in the received symbols, a decoding apparatus can detect the error and acquire the correct data through an iterative decoding process. The iterative decoding process is performed in a convolutional decoder or a turbo decoder of a receiver when the coding was achieved using the convolutional coding method or the turbo coding method. Meanwhile, when data is encoded by the RS coding method, an RS decoder in the receiver performs iterative decoding only for a particular case. A brief description will now be made of the RS coding and decoding methods.

FIG. 1 is a block diagram illustrating an internal structure of an apparatus with a general RS encoder, and an RS coding method. With reference to FIG. 1, a description will now be made of a structure of an RS coding apparatus, and an RS coding method.

The RS coding apparatus includes an RS encoder 110 and an RS coding buffer 120. FIG. 1 shows an apparatus that uses not only the RS coding method but also another coding method, by way of example. Therefore, the exemplary apparatus of FIG. 1 further includes a frame encoder 130 for encoding symbols output from the RS coding buffer 120 frame by frame.

A description will now be made of the RS coding method in terms of operations of the RS encoder 110 and the RS coding buffer 120. Transmission data is received frame by frame, and input to the RS coding buffer 120. Referring to FIG. 1, one frame has S symbols, and one symbol has b bits. Therefore, assuming that one frame has B bits, a relationship between S, B and b is given as “S=B/b”. A predetermined number ‘k’ of frames are stored in the RS coding buffer 120, and the RS encoder 110 generates (n-k) parity frames. Referring back to FIG. 1, the RS encoder 110 generates (n-k) parity symbols using a first symbol in a first frame through a first symbol in a k^{th} frame. That is, the RS encoder 110 generates parity symbols for a first symbol using the first symbols in the respective frames. The number of the generated parity symbols becomes (n-k). In the same method, the RS encoder 110 generates (n-k) parity symbols using second symbols in the first frame through the k^{th} frame. The RS encoder 110 can form parity symbols for all symbols in k frames by iterating the foregoing process S times, that is, as many times as the number of symbols existing in one frame. In other words, the RS encoder 110 can generate (n-k) parity frames for the symbols in the k frames. The generated parity frames are formed such that parity symbols generated using information symbols are located under a systematic frame formed with the information symbols. Therefore, the total number of RS-coded frames generated through the foregoing process becomes the sum ‘n’ of the number ‘k’ of systematic frames and the number ‘n-k’ of parity frames.

Therefore, n frames are sequentially encoded by the frame encoder 130 before being transmitted. The frame encoder 130, which is an inner encoder, adds cyclic redundancy check (CRC) bits to each of the frames, and encodes the CRC-added frames before transmission. The succeeding transmission process differs according to system. For example, a wired communication system performs a transmission process based on a transmission scheme required therein, and a wireless communication system performs a transmission process based on a transmission scheme required therein.

Next, the RS decoding process will be described herein below.

FIG. 2 is a block diagram illustrating an internal structure of an apparatus with a general RS decoder, and an RS decoding method. With reference to FIG. 2, a description will now be made of a structure of an RS decoding apparatus, and an RS decoding method.

An internal structure of an apparatus with an RS decoder of FIG. 2 is illustrated such that it corresponds to the structure of FIG. 1. Therefore, the apparatus of FIG. 2 includes a frame decoder 230, an RS decoding buffer 220, and an RS decoder 210. The frame decoder 230 performs frame decoding and CRC, and outputs decoded symbols frame by frame, and also outputs CRC results. The per-frame symbols and CRC results output from the frame decoder 230 are input to the RS decoding buffer 220. Therefore, as illustrated in FIG. 2, the RS decoding buffer 220 further includes an area for storing erasure bits.

The RS decoding buffer 220 will now be described. The RS decoding buffer 220 stores the decoded symbols that were decoded frame by frame. The frame symbols stored in the RS decoding buffer 220 have essentially the same format as the frame symbols that were encoded by the RS encoder 110 and then stored in the RS coding buffer 120 of FIG. 1. Therefore, one frame has B bits and S symbols. In addition, one symbol has b bits. However, the RS decoding buffer 220 is different from the RS coding buffer 120 in that each frame further has an erasure bit. Describing the RS decoding buffer 220 except for the erasure bits, each row becomes one frame and each column includes k information frames and (n-k) parity frames.

For a total of n frames stored in this method, the RS decoder 210 receives erasure bit information from the RS decoding buffer 220, reads symbols of each column, and performs RS decoding on the read symbols. The RS decoding process includes checking whether an error has occurred in a particular column, using k information symbols and (n-k) parity symbols. That is, the RS decoding process includes determining whether an error has occurred in the corresponding column, using (n-k) parity symbols generated using each column such as, for example, a first symbol stream that includes a first symbol through an (n-k)^{th} symbol in a first frame generated during transmission. The symbols read from the RS decoding buffer 220 are stored back in the RS decoding buffer 220 after being RS-decoded. By fully performing the foregoing process, the RS decoder 210 can detect a symbol position where an error has actually occurred. That is, if it is determined that there is an error in an erasure bit in a particular column and one error has occurred in a particular column in the RS decoding process, the RS decoder 210 can determine that symbols in a defective column detected in the RS decoding process are error symbols in the defective frame.

If an error is detected, the RS decoder 210 can correct the error by permorming a frame decoding process or a parity frame-based error correction process on the corresponding frame. That is, the RS decoder 210 restores the original data from the erasure information and the decoded frame data. The RS decoder 210 can correct all errors on the condition of Equation (1) below.
s+2e≦n−k (1)

In Equation (1), ‘s’ denotes the number of erasure symbols, and ‘e’ denotes the number of error symbols. In the exemplary structure of FIG. 2, the number of erasure symbols that can be detected is one for each frame. That is, an erasure symbol either exists or does not exist in the corresponding frame. Although it is checked that there is no erasure bit in an output of the frame decoder 230, a parity check result performed by the RS decoder 210 indicates that there is an error symbol. That is, although the frame checked by the frame decoder 230 has no error symbol, the same frame checked by the RS decoder 210 has error symbols. It can be understood from Equation (1)that the number of correctable erasure symbols are two times greater in number than the correctable error symbols.

As described above, in order to perform erasure decoding, the RS decoder 210 must use CRC information every frame. As a result, the RS decoder 210 cannot correctly detect an erasure position in a particular frame. In addition, because the erasure bits are set when an error occurs in even one symbol in one frame, and the CRC information indicates the occurrence of an error, all symbols in the corresponding frame are undesirably subject to erasure processing.

### SUMMARY OF THE INVENTION

It is, therefore, an object of the present invention to provide an apparatus and method for correctly decoding a concatenated RS code.

It is another object of the present invention to provide an apparatus and method for increasing decoding efficiency during decoding of a concatenated RS code.

According to one aspect of the present invention, there is provided an apparatus for receiving and decoding a double-coded symbol in a communication system using a double coding scheme for encoding a Reed-Solomon (RS)-coded symbol with a predetermined scheme for communication. The apparatus comprises an inner decoder for receiving a frame formed with the double-coded symbols, and primary-decoding the received frame. An RS decoding buffer stores an output of the inner decoder frame by frame. An RS decoder reads symbols in the same column from symbols of a frame stored in the RS decoding buffer, performs RS decoding on the read symbols, and generates an RS decodable indicator value for each symbol. A log likelihood ratio (LLR) update unit updates an LLR value using the RS decodable indicator value, and outputs the updated LLR value to the inner decoder.

According to another aspect of the present invention, there is provided an apparatus for receiving and decoding a double-coded symbol in a communication system using a double coding scheme for encoding a Reed-Solomon (RS)-coded symbol with a predetermined scheme for communication. The apparatus comprises an inner decoder for receiving a frame formed with the double-coded symbols, and primary-decoding the received frame. An RS decoding buffer stores an output of the inner decoder frame by frame. An RS decoder reads symbols of a frame stored in the RS decoding buffer column by column, performs RS decoding on the read symbols, and generates an RS decodable indicator value for each column. A log likelihood ratio (LLR) update unit updates an LLR value using the RS decodable indicator value, and outputs the updated LLR value. An iterative buffer receives the double-coded frames, applies an LLR value output from the LLR update unit to symbols in a corresponding frame, and provides, to the inner decoder, symbols in a frame to which the LLR value is applied during iterative decoding of the inner decoder.

According to still another aspect of the present invention, there is provided a method for receiving and decoding a double-coded symbol in a communication system using a double coding scheme for encoding a Reed-Solomon (RS)-coded symbol with a predetermined scheme for communication. The method includes receiving and storing the double-coded symbols, inner-decoding the received symbols according to the predetermined coding scheme, and storing the decoded symbols frame by frame. If the inner-coded frame can be subject to RS decoding, symbols in the store frame are read column by column, RS decoding is performed on the read symbols, and an RS decodable indicator value is generated for each symbol stream. A log likelihood ratio (LLR) value is updated using the RS decodable indicator value, and the inner decoding is re-performed using the LLR value.

### BRIEF DESCRIPTION OF THE DRAWINGS

The above and other objects, features and advantages of the present invention will become more apparent from the following detailed description when taken in conjunction with the accompanying drawings in which:

FIG. 1 is a block diagram illustrating an internal structure of an apparatus with a conventional RS encoder, and an RS coding method;

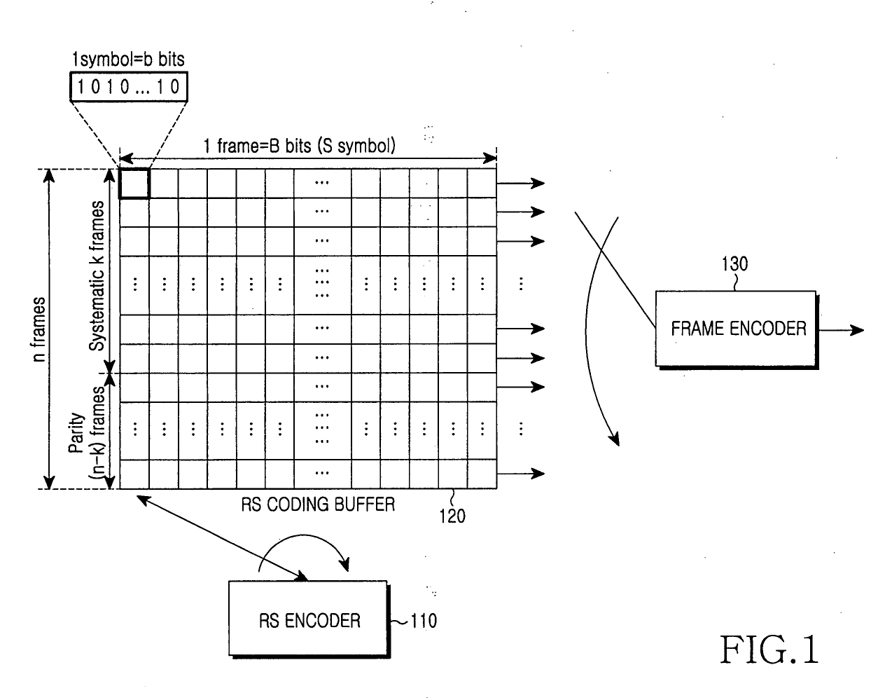

FIG. 2 is a block diagram illustrating an internal structure of an apparatus with a conventional RS decoder, and an RS decoding method;

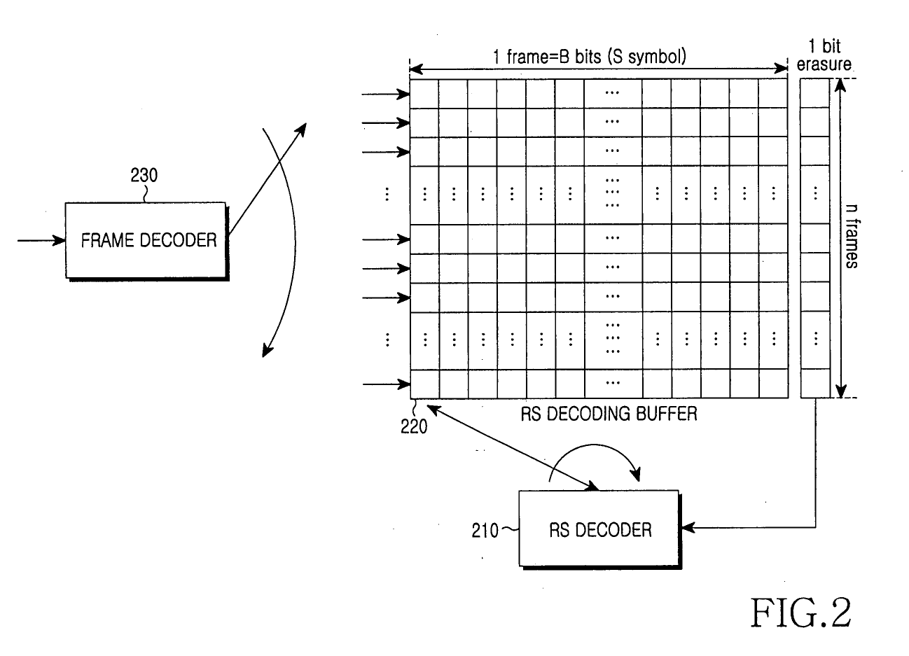

FIG. 3 is a block diagram illustrating an internal structure of an RS decoding apparatus according to a first embodiment of the present invention;

FIG. 4 is a flowchart illustrating a frame decoding process during RS decoding according to the first embodiment of the present invention;

FIG. 5 is a block diagram illustrating an internal structure of an RS decoding apparatus with an erasure function according to a second embodiment of the present invention;

FIG. 6 is a flowchart illustrating a frame decoding process during RS decoding according to the second embodiment of the present invention;

FIG. 7 is a block diagram illustrating an internal structure of an RS decoding apparatus for the case where there is a CRC per inner-coded frame according to a third embodiment of the present invention; and

FIG. 8 is a flowchart illustrating a frame decoding process during RS decoding according to the third embodiment of the present invention.

Throughout the drawings, like reference numbers will be understood to refer to like elements, features and structures.

### DETAILED DESCRIPTION OF EXEMPLARY EMBODIMENTS

Several exemplary embodiments of the present invention will now be described in detail with reference to the annexed drawings. In the following description, a detailed description of known functions and configurations incorporated herein has been omitted for clarity and conciseness.

Herein, an RS decoding apparatus and method will be separately described for the following three cases. First, a description will be made of an RS decoding method for the case where erasure decoding is not performed. Second, a description will be made of a per-symbol RS decoding method for the case where the general erasure decoding is possible. Third, a description will be made of a decoding method for additionally decoding a defective area for the case where erasure decoding is possible.

### First Embodiment

A first embodiment presents the general iterative decoding method not having an erasure function. A description will now be made of a structure and operation of an apparatus according to the first embodiment of the present invention.

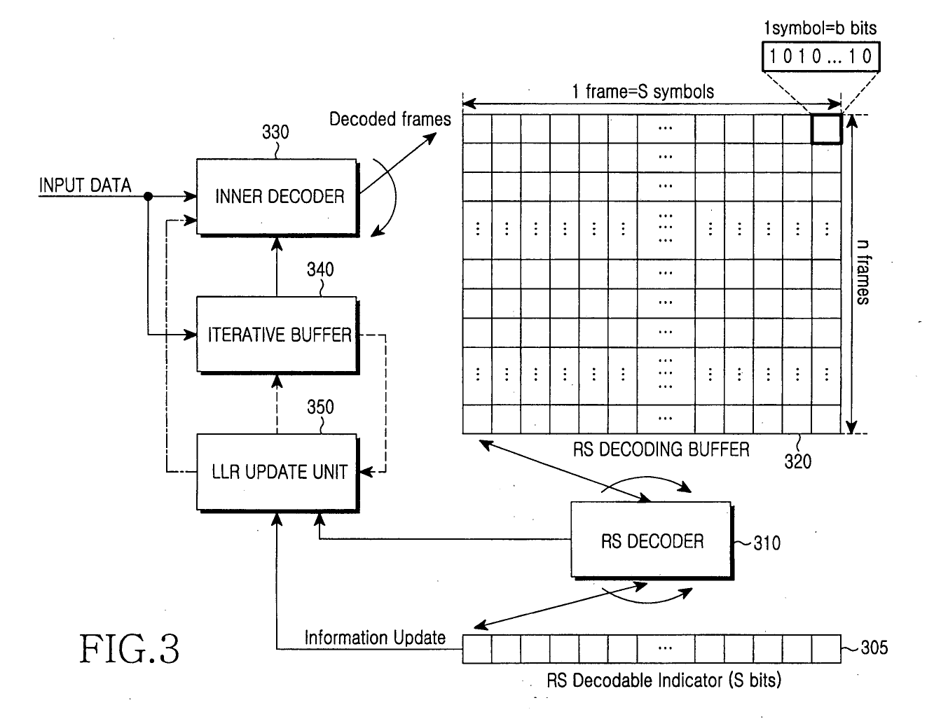

FIG. 3 is a block diagram illustrating an internal structure of an RS decoding apparatus according to a first embodiment of the present invention. With reference to FIG. 3, a detailed description will now be made of an internal structure and operation of an RS decoding apparatus according to the first embodiment of the present invention.

In FIG. 3, received transmission symbols are referred to as “input data.” The input data is applied to an inner decoder 330 and an iterative buffer 340. The inner decoder 330 decodes the input symbols frame by frame as described previously. The iterative buffer 340 stores the input data frame by frame. The apparatus according to the first embodiment of the present invention does not perform CRC, that is, does not detect erasure bits. Therefore, the data that was iterative-decoded in the inner decoder 330 frame by frame does not include a CRC result. The per-frame symbols output from the inner decoder 330 are input to an RS decoding buffer 320. The RS decoding buffer 320 stores the frame symbols without including a CRC result. That is, the RS decoding buffer 320 stores the values decoded in the inner decoder 330 in the order of being stored in the RS coding buffer 120 described previously.

In other words, in the data stored in the RS decoding buffer 320, one frame has S symbols and each symbol has b bits. That is, the RS decoding buffer 320 stores each of the frames formed in the foregoing method. The frames are divided into k information frames and (n-k) parity frames. This has been described previously, so a detailed description thereof will be omitted herein.

An RS decoder 310 reads symbols mapped to each column of the frames stored in the RS decoding buffer 320, and performs RS decoding on the read coded symbols. The RS decoder 310 according to embodiments of the present invention includes therein an algorithm for determining whether the symbols are decodable. The RS decoder 310 determines a period of RS decodable symbols through the algorithm for determining whether the symbols are inner-decodable. That is, because every frame has S symbols, the RS decoder 310 generates S RS decodable indicators 305. The RS decodable indicator is set to ‘enable’ when decoding is possible, and is set to ‘disable’ when decoding is impossible. After setting the RS decodable indicators 305, the RS decoder 310 does not perform RS decoding for the case where the RS decodable indicator 305 is set to ‘disable’.

Therefore, the RS decoder 310 performs RS decoding only for the case where the RS decodable indicator 305 is set to ‘enable’. Thereafter, the RS decoder 310 increases reliability for the corresponding bits in the iterative buffer 340 to an appropriate level for the symbol in the location where the RS decodable indictor 305 is set to ‘enable’. The RS decoder 310 outputs the set reliability value to a log likelihood ratio (LLR) update unit 350.

The LLR update unit 350 calculates an LLR value to be output to the inner decoder 330 or the iterative buffer 340, using the input reliability value and the RS decodable indicators 305. Thereafter, when the LLR update unit 350 desires to directly perform an LLR update, it directly outputs an LLR value to the inner decoder 330 for the LLR update, instead of updating an LLR value through the iterative buffer 340. On the contrary, when the LLR update unit 350 desires to indirectly update an LLR value, it outputs the LLR value to the iterative buffer 340. Therefore, the LLR update unit 350 outputs one signal. The LLR update unit 350 illustrated in FIG. 3 has two different doffed output lines. One of them is a double dotted line, which is input to the inner decoder 330, indicating the case where an LLR is updated through the direct method. The other dotted line is input to the iterative buffer 340, indicating the case where an LLR is updated through the indirect method. Thus, according to exemplary embodiments of the present invention, only one of the two signals is output from the LLR update unit 350.

If the LLR is updated in this manner, the inner decoder 330 facilitates decoding of received frames, contributing to an increase in decoding probability of received symbols. Thereafter, the per-frame symbols decoded again in the inner decoder 330 are input back to the RS decoding buffer 320, and then RS-decoded again in the RS decoder 310. This process is iterated until a predetermined iterative decoding stop condition is satisfied. The iterative decoding stop condition may indicate that the inner decoder 330 succeeds in decoding all symbols at or within a predetermined number of iterations.

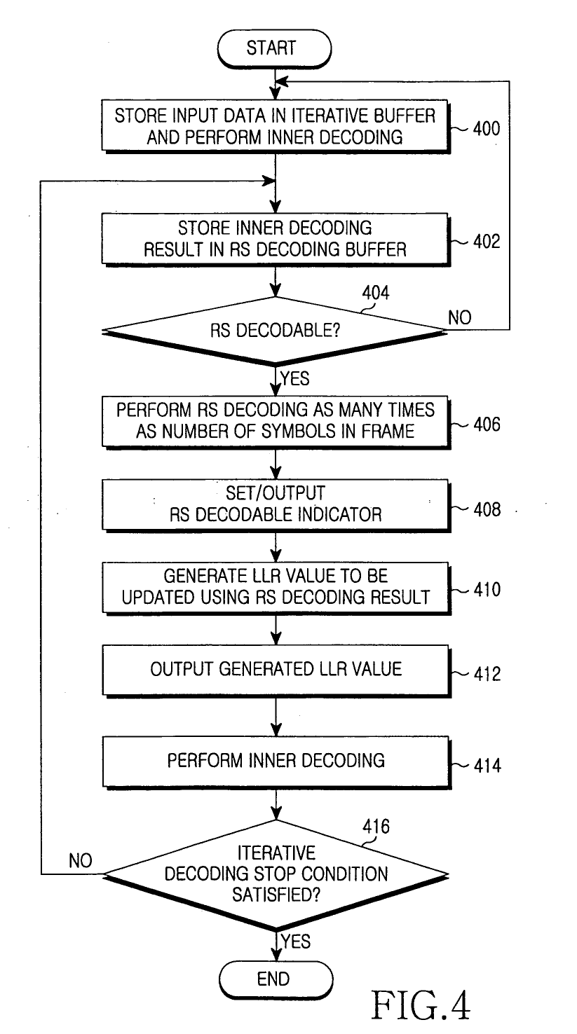

FIG. 4 is a flowchart illustrating a frame decoding process during RS decoding according to the first embodiment of the present invention. With reference to FIG. 4, a detailed description will now be made of a frame decoding process during RS decoding according to the first embodiment of the present invention.

Input data is applied to both an iterative buffer 340 and an inner decoder 330. In step 400, the inner decoder 330 performs inner decoding on the input data, and at the same time, the iterative buffer 340 stores the input data. In step 402, the inner decoder 330 stores the decoded symbols in an RS decoding buffer 320. In step 404, an RS decoder 310 determines whether RS decoding is possible. That is, the RS decoder 310 determines whether the data stored in the RS decoding buffer 320 is per-frame data encoded by the RS coding method. This will be described with reference to FIG. 3.

It is assumed that one frame has S symbols and one symbol has b bits. In addition, it is assumed that RS coding represents a process of generating (n-k) parity frames using k frames. In this case, the RS decoder 310 must receive n frames in order to make the RS decoding possible. Therefore, in step 404, the RS decoder 310 determines whether n frames have been stored in the RS decoding buffer 320.

If it is determined in step 404 that n frames have been stored, the RS decoder 310 reads symbols in the same column from the RS decoding buffer 320 and performs RS decoding on the read symbols in step 406. Herein, the RS decoder 310 performs RS decoding on each column and iterates the RS decoding S times because one frame has S symbols. However, if it is determined in step 404 that n frames have not been stored yet, that is, it is determined that decoding is not possible, the RS decoder 310 returns to step 400 and iterates steps 400 and 402 until RS decoding is possible.

After completing RS decoding on each column, the RS decoder 310 sets an RS decodable indicator 305 every column in step 408. The RS decodable indicator 305 is set with S bits every column. Further, after completing RS decoding on n frames, the RS decoder 310 outputs the RS indicator 305 to an LLR update unit 350 in step 408.

In step 410, the LLR update unit 350 updates an LLR value taking the RS decoding result into consideration. That is, the LLR update unit 350 updates an LLR value using the RS decodable indicator. The method of updating an LLR value can be performed by a direct update method and an indirect update method. As described above, the direct update method directly provides an updated LLR value to the inner decoder 330, and the indirect update method updates a value stored in the iterative buffer 340 using an LLR value, thereby providing an effect of indirectly updating an LLR value. Therefore, an LLR value generated to be updated in the LLR update unit 350 may differ according to the direct update method and the indirect update method. The LLR update unit 350, when it generates an LLR value to be updated, outputs the generated LLR value to the iterative buffer 340 or the inner decoder 330 according to a predetermined update method out of the direct update method and the indirect update method in step 412. In this manner, the LLR update unit 350 updates an LLR value.

Thereafter, in step 414, the inner decoder 330 re-performs inner decoding. After re-performing the inner decoding, the inner decoder 330 determines in step 416 whether an iterative decoding stop condition is satisfied. It will be assumed in FIG. 4 that the inner decoder 330 hardly succeeds in decoding through one decoding process. Therefore, when there is a high probability that the inner decoder 330 will succeed in decoding even with one iterative decoding, step 416 may be moved to another position. For example, step 416 may intervene between steps 400 and 402, between steps 402 and 404, or between steps 404 and 406. It is preferable to place step 416 between steps 404 and 406 because the RS decoding method is used. Alternatively, it is also possible to place step 416 under step 406.

Although there are several possible iterative decoding stop conditions, only two iterative decoding stop conditions will be mentioned herein. A first iterative decoding stop condition indicates the case where input data is fully decoded through the foregoing process. In this case, the inner decoder 330 stops the iterative decoding process. In the case where the input data is fully decoded, the iteration process is no longer required as all values in the RS decodable indicator are activated. A second iterative decoding stop condition indicates the case where the current iteration has reached a predetermined number of iterations. In this case, the inner decoder 330 cannot obtain a better decoding result even though it continuously performs the current decoding, or the inner decoder 330 can no longer perform iteration for decoding of the next data.

It is assumed that the foregoing process is performed in the environment where most errors occur during the first inner decoding. Therefore, step 416 for checking the iterative decoding stop condition is located at the bottom of the flowchart. However, if an error rate decreases during the first inner decoding, the checking position of the iterative decoding stop condition is changeable. For example, the iterative decoding stop condition may be checked between steps 402 and 404, between 404 and 406, or under step 406.

### Second Embodiment

Next, a description will be made of an iterative decoding method for the case where erasure decoding is possible.

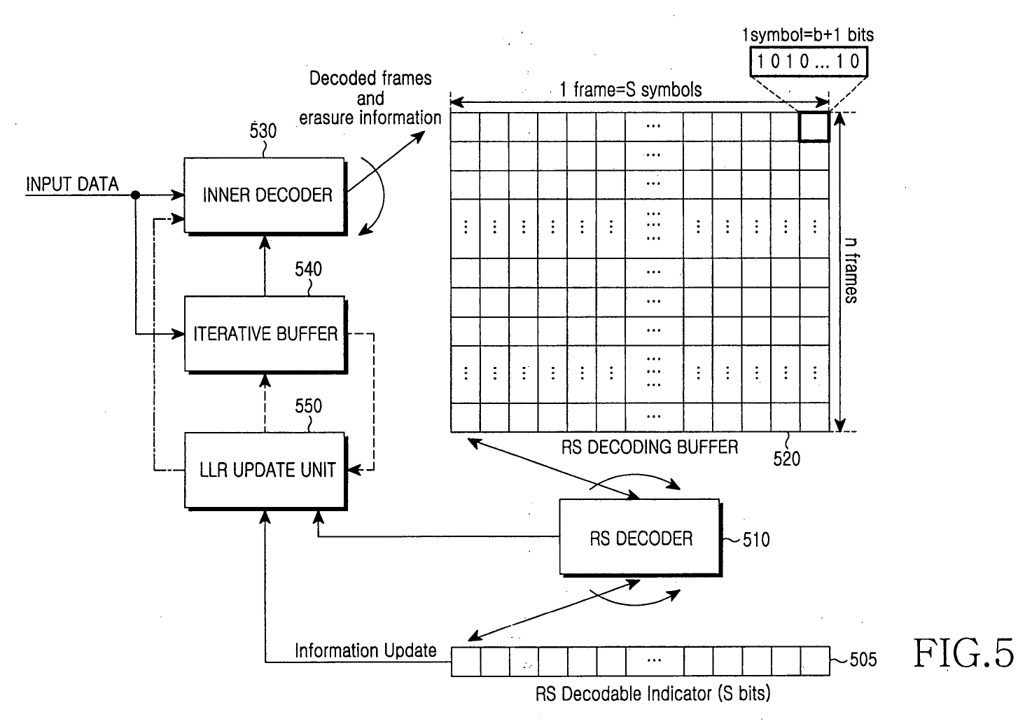

FIG. 5 is a block diagram illustrating an internal structure of an RS decoding apparatus with an erasure function according to a second embodiment of the present invention. With reference to FIG. 5, a detailed description will now be made of an internal structure and operation of an RS decoding apparatus with an erasure function according to the second embodiment of the present invention.

Similarly, received transmission symbols are called “input data.” The input data is applied to both an inner decoder 530 and an iterative buffer 540. The iterative buffer 540 stores the input data frame by frame. The inner decoder 530 decodes the input symbols frame by frame. The inner decoder 530 determines a decoding result of each symbol and an erasure value through a reliability check of each symbol according to the second embodiment of the present invention, and outputs the result values. The reliability check is performed to indicate how reliable the inner-decoded symbol is. For example, a reliability of the inner-decoded symbol is higher as the difference in probability between a particular value and another value is higher. Because one symbol output from the inner decoder 530 includes a reliability value in addition to the decoded symbol, the inner decoder 530 outputs b bits indicative of a decoding result of each symbol, and a 1-bit erasure value indicating a decoding result of the b bits and the reliability check result. Therefore, although one frame output from the inner decoder 530 according to the second embodiment of the present invention has S symbols, each symbol has (b+1) bits rather than b bits.

The apparatus according to the second embodiment of the present invention does not perform a CRC. Therefore, the data that was iterative-decoded in the inner decoder 530 frame by frame does not include a CRC result. The per-frame symbols output from the inner decoder 530 are applied to an RS decoding buffer 520. The RS decoding buffer 520 stores the per-frame symbols without the CRC result. Because each of the decoded symbols output from the inner decoder 530 has (b+1) bits unlike in the previously described embodiments, each of the symbols shown in FIG. 5 has (b+1) bits.

An overall description will now be made of the data stored in the RS decoding buffer 520. In the data stored in the RS decoding buffer 520, one frame has S symbols and each symbol has (b+1)bits of information according to the second embodiment of the present invention. This information is stored in the RS decoding buffer 520. The frames formed in this manner are divided into k information frames and (n-k) parity frames.

An RS decoder 510 reads symbols mapped to each column of the frames stored in the RS decoding buffer 520, and performs RS decoding on the coded symbols. For RS decoding, the RS decoder 510 according to the second embodiment of the present invention uses an erasure value indicating an erasure check result by the inner decoder 530. That is, during decoding, the RS decoder 510 performs erasure processing on the symbol checked as an erasure. In addition, the RS decoder 510 according to embodiments of the present invention includes therein an algorithm for determining whether the symbols are decodable. The RS decoder 510 determines a period of RS decodable symbols through the algorithm for determining whether the symbols are inner-decodable. That is, because every frame has S symbols, the RS decoder 510 generates S RS decodable indicators 505. The RS decodable indicator is set to ‘enable’ when decoding is possible, and is set to ‘disable’ when decoding is impossible. When the RS decodable indicator is set to ‘enable’ or ‘disable’, the erasure value is used together. After setting the RS decodable indicators 505, the RS decoder 510 does not perform RS decoding for the case where the RS decodable indicator 505 is set to ‘disable’.

That is, the RS decoder 510 performs RS decoding only for the case where the RS decodable indicator 505 is set to ‘enable’. Thereafter, the RS decoder 510 increases reliability for the corresponding bits in the iterative buffer 540 to an appropriate level for the symbol in the location where the RS decodable indictor 505 is set to ‘enable’. The RS decoder 510 outputs the set reliability value to an LLR update unit 550.

The LLR update unit 550 calculates an LLR value to be output to the inner decoder 530 or the iterative buffer 540, using the input reliability value and the RS decodable indicators 505. That is, when the LLR update unit 550 desires to directly perform an LLR update, it directly outputs an LLR value to the inner decoder 530 for the LLR update, instead of updating an LLR value through the iterative buffer 540. On the contrary, when the LLR update unit 550 desires to indirectly update an LLR value, it outputs the LLR value to the iterative buffer 540. Therefore, the LLR update unit 550 outputs one signal. The LLR update unit 550 illustrated in FIG. 5 has two different dotted output lines. One of them is a double dotted line, which is input to the inner decoder 530, indicating the case where an LLR is updated through the direct method. The other dotted line is input to the iterative buffer 540, indicating the case where an LLR is updated through the indirect method. Thus, according to exemplary embodiments of the present invention, only one of the two signals is output from the LLR update unit 550.

If the LLR is updated in this manner, the inner decoder 530 facilitates decoding of received frames, contributing to an increase in decoding probability of received symbols. Thereafter, the per-frame symbols decoded again in the inner decoder 530 are input back to the RS decoding buffer 520, and then RS-decoded again in the RS decoder 510. This process is iterated until a predetermined iterative decoding stop condition is satisfied. The iterative decoding stop condition may indicate that the inner decoder 530 succeeds in decoding all symbols at or within a predetermined number of iterations.

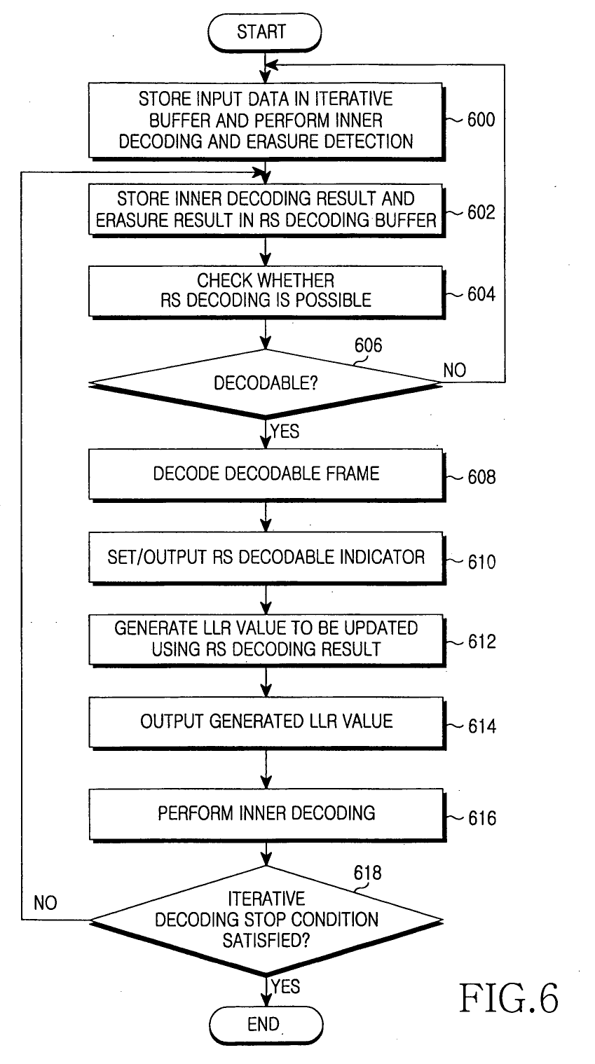

FIG. 6 is a flowchart illustrating a frame decoding process during RS decoding according to the second embodiment of the present invention. With reference to FIG. 6, a detailed description will now be made of a frame decoding process during RS decoding according to the second embodiment of the present invention.

Input data is applied to both an iterative buffer 540 and an inner decoder 530. In step 600, the inner decoder 530 performs inner decoding on the input data, and at the same time, the iterative buffer 540 stores the input data. After decoding the input data, the inner decoder 530 checks reliability and generates an erasure value which is set according to the reliability value.

The reliability represents a difference between trellis paths of values decoded during data decoding. That is, the reliability indicates a probability of 0 or a probability of 1 when a particular symbol has one of a value 0 and a value 1. As a particular symbol is higher in the probability of 0 or the probability of 1, its reliability is higher. As a decoded symbol is higher in probability of a particular value, that is, as the decoded symbol is higher in difference between a probability of the particular value and a probability of the other value is higher, its reliability is higher. An erasure value indicating this result is not set when a probability of a result value of a decoded symbol is higher than a predetermined probability, indicating that normal decoding is not possible. However, the erasures value is set when the probability of the result value of the decoded symbol is lower than the predetermined probability, indicating that the decoding result is reliable.

After performing the erasure check, the inner decoder 530 outputs each symbol with an erasure value. That is, in step 602, the inner decoder 530 outputs symbols with erasure values to an RS decoding buffer 520. The RS decoding buffer 520 stores the decoding result and the output symbol with an erasure value.

In step 604, an RS decoder 510 determines whether RS decoding is possible. That is, the RS decoder 510 determines whether the data stored in the RS decoding buffer 520 is RS-coded frame data. This will be described with reference to FIG. 5.

It is assumed that one frame has S symbols and one symbol has b bits. Because each symbol actually includes an erasure bit, it has (b+1) bits. Using the symbols formed in this way, the RS decoder 510 can check whether RS decoding is possible. In step 606, the RS decoder 510 determines whether RS decoding is possible. If it is determined in step 606 that RS decoding is possible, the RS decoder 510 proceeds to step 608, and otherwise, returns to step 600.

This is because the RS decoder 510 must receive a total of n frames in order to make the RS decoding possible, as described in the first embodiment. Therefore, if n frames have been received, the RS decoder 510 proceeds to step 608. Otherwise, the RS decoder 510 iterates steps 600 to 604 until the n frames are received.

In step 608, the RS decoder 510 checks erasure values and performs RS decoding on a column of decodable symbols. That is, if there is a value set as an erasure, the RS decoder 510 performs RS decoding without using this value. This process is iterated a total of S times because one frame has S symbols, as described in the first embodiment. Each time RS decoding of one symbol stream is completed, the RS decoder 510 generates an RS decodable indicator 505. Therefore, when RS decoding is fully completed, the RS decoder 510 generates a total of S RS decodable indicators. This process is performed in step 610.

The generated RS decodable indicator 505 is applied to an LLR update unit 550. The LLR update unit 550 generates an LLR value to be updated through either the direct update method or the indirect update method using the RS decodable indicator 505 received from the RS decoder 510. That is, the LLR value is applied to the inner decoder 530 in the direct update method, and to the iterative buffer 540 in the indict update method.

In step 616, the inner decoder 530 performs inner decoding using the value received through the foregoing process. In step 618, the inner decoder 530 checks whether an iterative decoding stop condition is satisfied, using the inner-decoded value. If it is determined in step 618 that the iterative decoding stop condition is satisfied, the inner decoder 530 ends the routine. However, if the iterative decoding stop condition is not satisfied, the inner decoder 530 returns to step 600 and iterates the foregoing process. The iterative decoding stop condition is equal to that described in the first embodiment, so a detailed description thereof will not be given.

Similarly, in FIG. 6, a position of checking whether the iterative decoding stop condition is satisfied may intervene between steps 606 and 608, or may move to other places. As described in the first embodiment, the change in the position depends on the probability that the inner decoder 530 will succeed in decoding with one iteration.

### Third Embodiment

Finally, a description will now be made of an iterative decoding method for the case where there is a CRC per inner-coded frame. It will be assumed herein that CRC and erasure decoding is possible.

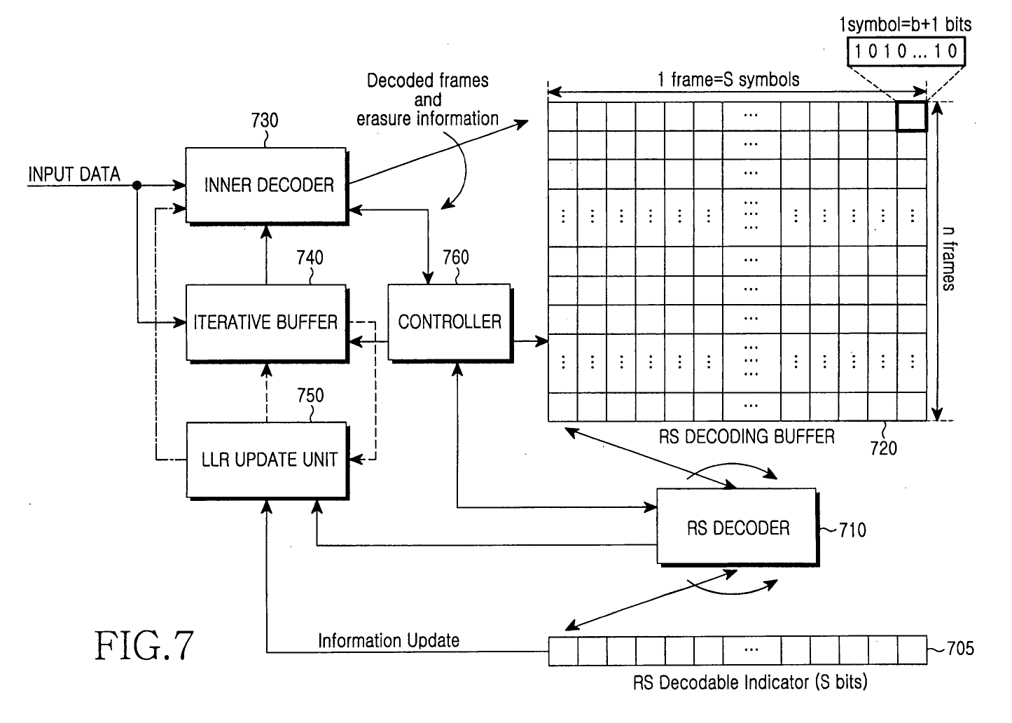

FIG. 7 is a block diagram illustrating an internal structure of an RS decoding apparatus for the case where there is a CRC per inner-coded frame according to a third embodiment of the present invention. With reference to FIG. 7, a detailed description will now be made of an internal structure and operation of an RS decoding apparatus for the case where there is a CRC per inner-coded frame according to the third embodiment of the present invention.

A decoding method used in the third embodiment of the present invention will now be described in a general way. The exemplary decoding method uses a CRC technique. Therefore, in the exemplary decoding method, a frame with a ‘good’ CRC check result has no error. Accordingly, there is a need to separately store the frame with a ‘good’ CRC result in an iterative buffer 740. If the number of frames with a ‘bad’ CRC result is (n-k) or less, all errors can be corrected by an RS decoder 710. In this case, the decoding apparatus does not perform iterative decoding. Such an operation will now be described in more detail herein below.

Similarly, received transmission symbols are called “input data.” The input data is applied to both an inner decoder 730 and an iterative buffer 740. The iterative buffer 740 stores the input data frame by frame. The inner decoder 730 decodes the input symbols frame by frame. As described in the second embodiment of the present invention, the inner decoder 730 checks a decoding result of each symbol and an erasure value through reliability check of each symbol, and outputs the result values. That is, the inner decoder 730 outputs b bits indicative of a decoding result of each symbol, and a 1-bit erasure value indicating a decoding result of the b bits and the reliability check result, together. In addition, the inner decoder 730 performs a CRC check using CRC information included in each frame according to the third embodiment of the present invention. Therefore, one frame output from the inner decoder 730 according to the third embodiment of the present invention has S symbols, but each symbol has (b+1) bits rather than b bits.

As briefly described above, the apparatus according to the third embodiment of the present invention performs a CRC check. Because a CRC check is performed, a frame with a ‘good’ CRC result has no errors. Accordingly, there is no need to separately store the frame with a ‘good’ CRC result in the iterative buffer 740. Therefore, the inner decoder 730 deletes the input data with a ‘good’ CRC result from the iterative buffer 740. The operation of deleting a frame stored in the iterative buffer 740 is achieved by a controller 760 by controlling the iterative buffer 740 using a CRC result output from the inner decoder 730. Therefore, only the frames with an error among the frames decoded in the inner decoder 730 are stored in the iterative buffer 740. If the number of frames with an error is (n-k) or less, the errors can be fully corrected by the RS decoder 710, so the decoding apparatus does not perform iterative decoding. In this case, the RS decoder 710 outputs decoded signals for all of the frames, and upon receiving the corresponding information, the controller 760 deletes the frames stored in the iterative buffer 740.

This process is performed on n frames. That is, the process is performed until as many frames as the number ‘n’ of RS decodable frames. Therefore, all frames are stored in the RS decoding buffer 720 regardless of their CRC results. In addition, because each symbol of a frame stored in the RS decoding buffer 720 have its associated erasure bit, the RS decoder 710 performs RS decoding using data stored in the RS decoding buffer 720, a reliability value, and CRC result information output from the controller 760. If the controller 760 does not provide CRC result information to the RS decoder 710, the inner decoder 730 can be designed such that it outputs the CRC result to the RS decoding buffer 720. In this case, the RS decoding buffer 720 must further include an area for storing the CRC result.

A description will now be made of the RS decoder 710. The RS decoder 710 performs RS decoding S times because one frame has S symbols. If the number of bad-CRC frames is less than or equal to (n-k), the RS decoder 710 can perform decoding, disregarding the reliability of the symbols. The RS decoder 710 detects the bad-CRC frames through the controller 760, and performs erasure processing on all symbols in the bad-CRC frames, performing the decoding. Thereafter, because the decoding process is no longer required, the RS decoder 710 sets all RS decodable indictors generated therein to ‘enable’, to thereby complete the decoding process.

However, if the number of bad-CRC frames is greater than (n-k), the symbol determined as an erasure in the inner decoder 730 is used as an erasure symbol during RS decoding. In this case, the RS decoder 710 sets an RS decodable indicator to ‘enable’ for a period where an RS decoding is possible through its algorithm for determining whether decoding is possible. However, the RS decoder 710 sets the RS decodable indicator to ‘disable’ for a period where RS decoding is possible, and does not perform RS decoding. In this case, if the number of erasures is less than or equal to (n-k) in each RS decoding period, the RS decodable indicator is set to ‘enable’ to indicate that RS decoding in the corresponding period is possible.

An LLR update unit 750 increases a reliability of corresponding bits in the iterative buffer 740 to an appropriate level for the symbol in a position where an RS decodable indicator 705 output from the RS decoder 710 is set to ‘enable’, so that the RS decoding result is reflected during the inner decoding. As in the first and second embodiments, the LLR update unit 750 can be either implemented with the method of changing a data value in the iterative buffer 740, denoted by a dotted line, or implemented with the method of changing an LLR value of a corresponding symbol by directly connecting with the inner decoder 730, denoted by a double dotted line. These methods have been described in the first and second embodiments.

Thereafter, the inner decoder 730 sequentially re-reads data in the iterative buffer 740, and iterates the inner decoding and the RS decoding on the read data several times. If a bad-CRC frame is changed to a good-CRC frame through the iterative decoding, the inner decoder 730 provides corresponding information to the controller 760 so that the receiver recognizes that the corresponding frame is a good-CRC frame, and the iterative buffer 740 deletes the frame. In the course of iterating the processes, if an iterative decoding stop condition is satisfied, the inner decoder 730 stops the iterative decoding and outputs the decoding result. One of the iterative decoding stop conditions includes the case where no more iteration is required as all values in the RS decodable indicator 705 are set to ‘enable’. Also, the iterative decoding stop conditions include those described in the first and second embodiments.

If the capacity of the iterative buffer 740 is limited to L frames in the iterative decoding method having an erasure decoding function that relies on the CRC result, a frame that failed to be stored in the iterative buffer 740 due to the limited capacity even though its CRC result is ‘bad’ cannot be subject to iterative decoding, so that the entire data in the frame must undergo erasure processing. Therefore, when the number S of bad-CRC frames is given as Equation (2) below, the decoder in the receiver cannot correct errors.
n-k+L<S (2)

In Equation (2), ‘n-k’ denotes the number of parity frames, and L denotes the capacity of the iterative buffer.

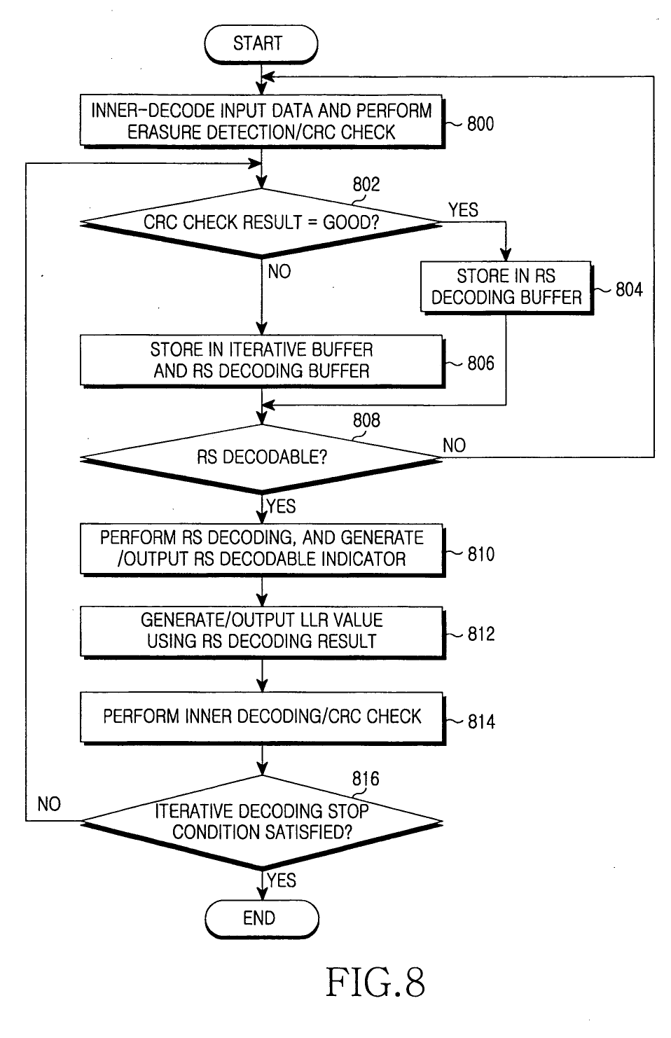

FIG. 8 is a flowchart illustrating a frame decoding process during RS decoding according to the third embodiment of the present invention. With reference to FIG. 8, a detailed description will now be made of a frame decoding process during RS decoding according to the third embodiment of the present invention.

Input data is applied to both an iterative buffer 740 and an inner decoder 730. However, the iterative buffer 740 may not store the input data when its capacity is low. It will be assumed herein that the capacity of the iterative buffer 740 is low. In step 800, the inner decoder 730 performs inner decoding on the input data. The inner decoder 730 detects an erasure value of each symbol while performing the inner decoding, and performs CRC check after completion of inner decoding on all symbols in one frame.

Thereafter, the inner decoder 730 checks whether a CRC result is ‘good’ in step 802. If it is determined in step 802 that the CRC result is ‘good’, the inner decoder 730 stores the inner-decoded frame only in an RS decoding buffer 720 in step 804. However, if the CRC result is not ‘good’, the inner decoder 730 proceeds to step 806 where it stores the inner decoding result in the RS decoding buffer 720 and delivers a unique number of the decoded frame to a controller 760 so that it stores the input data in the iterative buffer 740.

After step 804 or 806, the controller 760 determines in step 808 whether RS decoding is possible. If the RS decoding is possible, the controller 760 proceeds to step 810, and otherwise, returns to step 800. The cases where the RS decoding is possible have been described in the prior art section and the first and second embodiments, so a detailed description thereof will not be given herein for simplicity. If it is determined in step 808 that RS decoding is not possible, the controller 760 iteratively performs steps 800 to 808.

In step 810, an RS decoder 710 performs RS decoding and generates an RS decodable indicator 705. If the number of bad-CRC frames is less than (n-k) during the RS decoding, the RS decoder 710 does not generate the RS decodable indicator 705 because it can immediately complete the decoding. However, if the number of bad-CRC frames is greater than (n-k) during the RS decoding, the RS decoder 710 generates the RS decodable indicator 705 because it cannot restore other symbols with only the RS decoding.

Thereafter, in step 812, the RS decoder 710 outputs the generated RS decodable indicator 705 to an LLR update unit 750. The LLR update unit 750 generates an LLR value to be updated through either the direct update method or the indirect update method using the RS decodable indicator 705 provided from the RS decoder 710. That is, the LLR update unit 750 outputs the LLR value to the inner decoder 730 in the direct update method, and to the iterative buffer 740 in the indirect update method.

In step 814, the inner decoder 730 performs inner decoding using the value received through the foregoing process. In step 816, the inner decoder 730 checks whether an iterative decoding stop condition is satisfied, using the inner-decoded values. If it is determined in step 816 that the iterative decoding stop condition is satisfied, the inner decoder 730 ends the routine. However, if the iterative decoding stop condition is not satisfied, the inner decoder 730 returns to step 800 and iterates the foregoing process. The iterative decoding stop condition is equal to that described in the first and second embodiments, so a detailed description thereof will not be given.

Similarly, in FIG. 8, a position of checking whether the iterative decoding stop condition is satisfied may intervene between steps 808 and 810, or may move to other places. As described in the first embodiment, the change in the position depends on the probability that the inner decoder 730 will succeed in decoding with one iteration.

As can be understood from the foregoing description, the novel apparatus and method for decoding a concatenated RS code uses an inner decoding result without determining an erasure value of a symbol simply depending on a CRC result, thereby obtaining the maximum reception performance of the concatenated RS code and thus providing improved decoding performance. In addition, the improved reception method proposed by the present invention decreases a size of an interleaver for a concatenated code in a transmitter, thereby contributing to a reduction in initial reception delay time.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. An apparatus for receiving and decoding a double-coded symbol in a communication system using a double coding scheme for encoding a Reed-Solomon (RS)-coded symbol with a predetermined scheme for communication, the apparatus comprising:
an inner decoder for receiving a frame formed with the double-coded symbols, and primary-decoding the received frame;
an RS decoding buffer for storing an output of the inner decoder frame by frame;
an RS decoder for reading symbols in the same column from symbols of a frame stored in the RS decoding buffer, performing RS decoding on the read symbols, and generating an RS decodable indicator value for each symbol; and
a log likelihood ratio (LLR) update unit for updating an LLR value using the RS decodable indicator value, and outputting the updated LLR value to the inner decoder.

2. The apparatus of claim 1, further comprising an iterative buffer for storing the double-coded per-frame symbols, receiving the LLR value, and providing the received coded frame symbols to the inner decoder during iterative decoding on the received frame.

3. The apparatus of claim 1, wherein the inner decoder checks reliability of each symbol, generates an erasure value of each symbol as a reliability check result value, and outputs the decoded value of each symbol and the erasure value together.

4. The apparatus of claim 3, wherein the RS decoder performs RS decoding using the decoded value of each symbol and the erasure value.

5. The apparatus of claim 3, wherein if cyclic redundancy check (CRC) on the double-coded symbols is possible, the inner decoder performs CRC on the double-coded symbols and outputs a CRC result.

6. The apparatus of claim 5, wherein the RS decoder performs RS decoding using the CRC result output from the inner decoder.

7. An apparatus for receiving and decoding a double-coded symbol in a communication system using a double coding scheme for encoding a Reed-Solomon (RS)-coded symbol with a predetermined scheme for communication, the apparatus comprising:
an inner decoder for receiving a frame formed with the double-coded symbols, and primary-decoding the received frame;
an RS decoding buffer for storing an output of the inner decoder frame by frame;
an RS decoder for reading symbols of a frame stored in the RS decoding buffer column by column, performing RS decoding on the read symbols, and generating an RS decodable indicator value for each column;
a log likelihood ratio (LLR) update unit for updating an LLR value using the RS decodable indicator value, and outputting the updated LLR value; and
an iterative buffer for receiving the double-coded frames, applying an LLR value output from the LLR update unit to symbols in a corresponding frame, and providing, to the inner decoder, symbols in a frame to which the LLR value is applied during iterative decoding of the inner decoder.

8. The apparatus of claim 7, wherein the inner decoder checks reliability of each symbol, generates an erasure value of each symbol as a reliability check result value, and outputs the decoded value of each symbol and the erasure value together.

9. The apparatus of claim 8, wherein the RS decoder performs RS decoding using the decoded value of each symbol and the erasure value.

10. The apparatus of claim 8, wherein if cyclic redundancy check (CRC) on the double-coded symbols is possible, the inner decoder performs CRC on the double-coded symbols and outputs a CRC result.

11. The apparatus of claim 10, wherein the RS decoder performs RS decoding using the CRC result.

12. A method for receiving and decoding a double-coded symbol in a communication system using a double coding scheme for encoding a Reed-Solomon (RS)-coded symbol with a predetermined scheme for communication, the method comprising the steps of:
receiving and storing the double-coded symbols, inner-decoding the received symbols according to the predetermined coding scheme, and storing the decoded symbols frame by frame;
reading symbols in the store frame column by column, performing RS decoding on the read symbols, and generating an RS decodable indicator value for each symbol stream if the inner-coded frame can be subject to RS decoding; and
updating a log likelihood ratio (LLR) value using the RS decodable indicator value, and re-performing the inner decoding using the LLR value.

13. The method of claim 12, further comprising the steps of:
checking whether an iterative decoding stop condition is satisfied, each time the primary decoding is completed; and
stopping the decoding if the iterative decoding stop condition is satisfied.

14. The method of claim 13, wherein the inner decoding step comprises the step of checking reliability of each symbol, generating an erasure value of each symbol as a reliability check result value, and outputting the decoded value of each symbol and the erasure value together.

15. The method of claim 14, wherein the RS decoding step comprises the step of performing RS decoding using the decoded value of each symbol and the erasure value.

16. The method of claim 12, wherein the RS decodable indicator value is applied to the double-coded symbols during iterative decoding.

17. The method of claim 12, wherein the RS decodable indicator value is applied to the inner decoding during iterative decoding.

18. The method of claim 14, wherein the inner decoding step comprises the step of performing cyclic redundancy check (CRC) on the double-coded symbols and outputting a CRC result, if CRC on the double-coded symbols is possible.

19. The method of claim 18, wherein the RS decoding step comprises the step of performing RS decoding using the CRC result.
